(19) United States
(12) Patent Application Publication
(10) Pub. No.: US 2006/0062340 A1
(43) Pub. Date: Mar. 23, 2006

(54) Phase adjuster

(75) Inventor: Dong Zheng, San Jose, CA (US)

Correspondence Address: Lowell W. Gresham;Meschkow & Gresham, PLC, Suite 409, 5727 North Seventh Street, Phoenix, AZ, 85014, US

(73) Assignee: Intersil Americas, Inc., Milpitas, CA (US)

(21) Appl. No.: 10/992,537

(22) Filed: Nov. 17, 2004

Related U.S. Application Data
(60) Provisional application No. 60/611,483, filed on Sep. 20, 2004.

(51) Int. Cl. H03D 3/24; H03L 7/00

(52) U.S. Cl. 375/376; 327/161

(57) ABSTRACT

A phase adjuster (10) includes a delay-locked loop (14) and an interpolator (34). The delay-locked loop (14) includes a sufficient number of delay stages (24) to maintain a Π/2 radians phase shift across the one delay stage (24′) of a voltage-controlled delay line (20). The output signals (28 and 30) to this one stage (24′) are filtered, output from the delay-locked loop (14), and input to the interpolator (34). Within the interpolator (34), these output signals (28 and 30) are weighted and combined. The ratio of the weighting applied to the output signals determines the resulting adjusted phase of an output clock signal (36). The weighting can be a time-varying signal or otherwise programmed as needed to achieve a desired phase shift that is independent of clock speed and process variation.

### RELATED INVENTION

The present invention claims benefit under 35 U.S.C. §119(e) to “Phase Adjuster,” U.S. Provisional Patent Application Ser. No. 60/611,483, filed 20 Sep. 2004, which is incorporated by reference herein.

### TECHNICAL FIELD OF THE INVENTION

The present invention relates generally to the field of clock management for electronic circuits. More specifically, the present invention relates to clock management circuits in which the phase of a clock signal may be programmed.

### BACKGROUND OF THE INVENTION

Synchronous circuits rely on synchronized clock signals. For example, when two circuits are arranged sequentially, a first circuit applies some processing to an input signal in response to a first edge of a clock signal. This processing produces a resulting signal that is then presented to a second circuit. In response to a subsequent edge of the clock signal, the second circuit then accepts the resulting signal and applies its own processing to the resulting signal. But the signal clocking the second circuit is often not precisely the same signal that clocks the first circuit. While the basic timing may originate with a common clock signal, the actual clock signals clocking different circuits are invariably transmitted to different locations, buffered, gated, or otherwise processed so that some relative skew results.

As on-chip clock rates have increased, the precise timing of various clock signals has become more critical. In many high-speed applications, clock signals having programmable phase are used to either eliminate the relative skew or to control the skew to achieve a desired phasing.

While numerous techniques are known for adjusting the phase of a clock signal, many of such techniques pose problems when applied within integrated circuits (ICs). For example, many conventional phase adjustment techniques employ resistor-capacitor networks or other circuits that apply predetermined amounts of time delay to a clock signal whose phase is being adjusted. Such techniques unfortunately depend upon a clock signal exhibiting a predetermined period and reduce the ability of the circuit to operate over a range of clock periods. Moreover, such techniques are often process dependent. In other words, the vagaries of the IC manufacturing process implement different delays in different batches of ICs.

Another problem with conventional clock-signal-phase-adjustment techniques is that they permit phase or timing adjustment only in crude discrete steps. The circuit complexity required to achieve very small steps is typically impractical, so undesirably large steps are enacted. As a result, more delay than would be optimally desired is typically inserted into the effected clock signals and system performance is degraded.

### SUMMARY OF THE INVENTION

It is an advantage of the present invention that an improved clock phase adjuster is provided.

Another advantage of the present invention is that a clock phase adjuster that is independent of IC processing vagaries is provided.

Yet another advantage of the present invention is that a clock phase adjuster is provided that may be continuously adjustable and have no minimum step size.

These and other advantages are realized in one form by an improved phase adjuster. The phase adjuster includes a delay-locked loop configured to receive a periodic input signal and to generate a first output signal phase-shifted N·Π radians from the input signal, where N is an integer number greater than or equal to one. The delay-locked loop is also configured to generate a second output signal phase-shifted by an amount other than N·Π radians from the input signal. The phase adjuster also includes an interpolator configured to receive the first and second output signals and a control signal. The interpolator is also configured to output a phase-adjusted signal having a phase relative to the periodic input signal determined in response to the control signal.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a block diagram of one embodiment of a clock phase adjuster in accordance with the teaching of the present invention;

FIG. 2 shows a timing diagram which depicts operation of a delay-locked loop portion of the clock phase adjuster of FIG. 1;

FIG. 3 shows a schematic diagram of one embodiment of an interpolator portion of the clock phase adjuster of FIG. 1;

FIG. 4 shows a block diagram of a digital control element which may be used in one embodiment of the present invention to adjust clock phase; and

FIG. 5 shows a block diagram of a second embodiment of a clock phase adjuster in accordance with the teaching of the present invention.

### DETAILED DESCRIPTION OF THE PREFERRED EMBODIMENTS

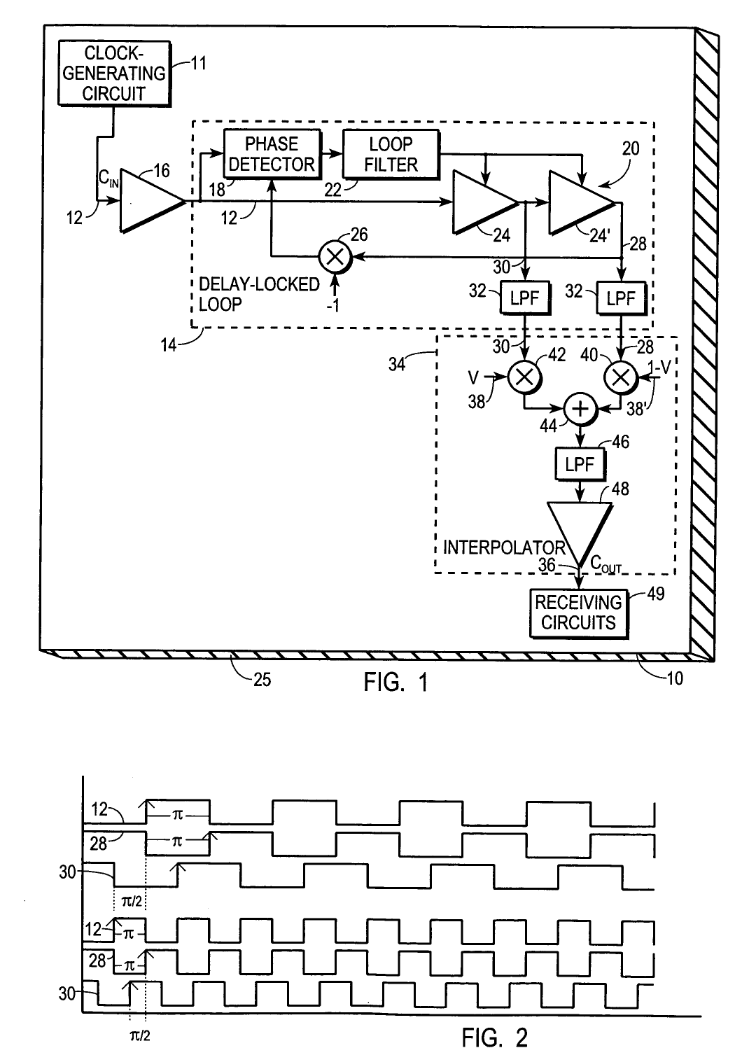

FIG. 1 shows a block diagram of one embodiment of a clock phase adjuster 10 in accordance with the teaching of the present invention. A clock generating circuit 11 generates a periodic input signal 12, referred to herein as source clock signal 12 or input clock signal 12, which is routed to a delay-locked loop (DLL) 14, through an optional buffer 16. Then, clock signal 12 is routed to a phase detector 18 and a voltage-controlled delay line 20. An output from phase detector 18 feeds a loop filter 22, and the output of loop filter 22 drives control inputs for delay line 20.

Delay line 20 includes one or more delay stages 24. In the preferred embodiment, two of delay stages 24 are included. Each delay stage 24 may be configured as a buffer or inverter. The amount of delay imposed at each stage 24 is determined in response to the control voltage applied from loop filter 22 at the control input of each stage 24.

Desirably, each delay stage 24 is configured as precisely identical to the others as is practical, and desirably delay-locked loop 14 in particular, and clock phase adjuster 10 in general, is implemented on a solitary semiconductor substrate 25 (i.e., within a single integrated circuit) so that symmetry between delay stages 24 is high. Symmetry between delay stages 24 causes each delay stage 24 to implement substantially the same phase delay as the others when a common control voltage is applied at the control inputs of the stages 24. By integrally forming delay-locked loop 14 on solitary semiconductor substrate 25, the vagaries of semiconductor processing may be compensated. Different delay stages 24 manufactured in different semiconductor batches may exhibit different delay characteristics, but on any solitary semiconductor substrate 25, delay characteristics should be substantially equal.

An output from a final delay stage 24′ in delay line 20 is an ultimate-delayed clock signal 28. Ultimate-delayed clock signal 28 is fed back to phase detector 18. In the preferred embodiment, this signal 28 is fed back through an inversion element 26. The preferred embodiment is implemented using differential signals, and inversion element 26 is implemented by swapping signal lines of the differential signal output from final delay stage 24 before applying it to phase detector 18.

FIG. 2 shows a timing diagram which depicts operation of delay-locked loop 14. Referring to FIGS. 1 and 2, at steady state, delay elements 24 insert the amount of delay into input clock signal 12 that causes ultimate-delayed clock signal 28 to match the phase of input clock signal 12 at phase detector 18. This matching occurs at a subsequent clock cycle of input signal 12. In other words, ultimate-delayed clock signal 28 is delayed N·Π radians from input clock signal 12, where N is an integer number greater than or equal to one. FIGS. 1 and 2 depict an embodiment of the present invention where N=1, but this is not a requirement. Ultimate-delayed clock signal 28 is held in phase coherence (i.e., locked in phase) with input clock signal 28 by the operation of a feedback loop established through the control inputs of delay stages 24 in delay-locked loop 14.

In the preferred embodiment depicted in FIGS. 1 and 2, each of the depicted two delay stages 24 implements a delay equivalent to Π/2 radians of phase shift, and the inversion of ultimate-delayed clock signal 28 prior to its application at phase detector 18 causes another n radians in phase change without imposing any significant delay. Through the tracking ability of delay-locked loop 14, the delay equivalent to Π/2 radians of phase shift imposed by delay elements 24 tracks input clock signal 12 as the frequency or period of clock signal 12 changes. In other words, this phase shift is independent of the frequency of input clock signal 12, as depicted by the differences between the top and bottom sets of three traces in FIG. 2. The amount of delay imposed by delay stages 24 will adjust to clock speed so that the Π/2 radians of phase shift remains constant as clock period changes. And, the amount of delay imposed by delay stages 24 is independent of semiconductor processing vagaries, unlike circuits that depend on capacitance and/or resistance values to establish delay durations.

Since each delay stage 24 implements Π/2 radians of phase shift in this preferred embodiment, regardless of clock frequency, a penultimate-delayed clock signal 30 leads ultimate-delayed clock signal 28 by Π/2 radians. Thus, ultimate- and penultimate-delayed clock signals 28 and 30 are locked in a phase quadrature relationship, with ultimate-delayed clock signal 28 exhibiting a SIN phase relative to a COS phase exhibited by penultimate-delayed clock signal 30.

Ultimate- and penultimate-delayed clock signals 28 and 30 are first filtered in low pass filters (LPFs) 32, then output from DLL 14. Low pass filters 32 are configured to remove higher harmonics and convert ultimate- and penultimate-delayed clock signals 28 and 30 into sinusoidal signals. Desirably, low pass filters 32 are configured as identically as practical to maintain the above-discussed quadrature relationship.

The above-discussed embodiment of delay-locked loop 14 is not the only one that will suffice for use in connection with the present invention. For example, four delay stages 24 may be used without an inversion in ultimate-delayed clock signal 28 prior to application to phase detector 18. Such an embodiment might be desirable where clock generating circuit 11 causes source clock signal 12 to exhibit a duty cycle other than 50%. In another example, although more complicated, a number of delay stages 24 may be used that causes something other than Π/2 radians of phase shift between the clock signals 28 and 30 output from delay-locked loop 14. In still another example, one or more additional delay stages 24, substantially identical to the previous delay stages 24, may be cascaded after ultimate stage 24′. While the additional delay stages 24 would not be included in the feedback loop they could produce another version of penultimate-delayed clock signal 30 that would nevertheless be substantially phase locked at a predetermined phase difference to ultimate-delayed clock signal 28. In yet another embodiment, the function provided by low pass filters 32 could be implemented by limiting the bandwidth of the buffers.

Ultimate- and penultimate-delayed clock signals 28 and 30 are routed to an interpolator 34. Interpolator 34 generates an output clock signal 36 that exhibits a phase interpolated between the quadrature phases of clock signals 28 and 30. The precise output phase is determined in response to a control input 38, depicted in FIG. 1 as the variables “V” and “1−V”. With appropriate inversions of delayed signals 28 and 30 and/or control input signals 38, all quadrants can be represented, so a full 2Π radians of phase control are provided.

In particular, ultimate-delayed clock signal 28 is routed to a first input of an analog multiplier 40, and a continuously adjustable, analog control input 38′ which conveys the “1−V” control, is applied to a second input of multiplier 40. Penultimate-delayed clock signal 30 is routed to a first input of an analog multiplier 42, and continuously adjustable, analog control input 38, which conveys the “V” control, is applied to a second input of multiplier 42. Scaled signals provided by outputs of multipliers 40 and 42 are routed to first and second inputs of an adder 44. Adder 44 combines the scaled signals, and an output of adder 44 provides output clock signal 36, after filtering in an optional low pass filter 46 and buffering in an optional buffer 48. Optional buffer 48 permits output clock signal 36 to maintain a constant amplitude as control voltages change. Output clock signal 36 is then routed to any of a wide variety of receiving circuits 49, which are responsive to clock signal 36.

Accordingly, output clock signal 36 can be expressed as:
C_{OUT}=V·SIN(ωt)+(1−V)·COS(ωt). EQ. 1
And, the resulting phase can be expressed as:
Φ=TAN⁻¹([1−V]/V). EQ. 2

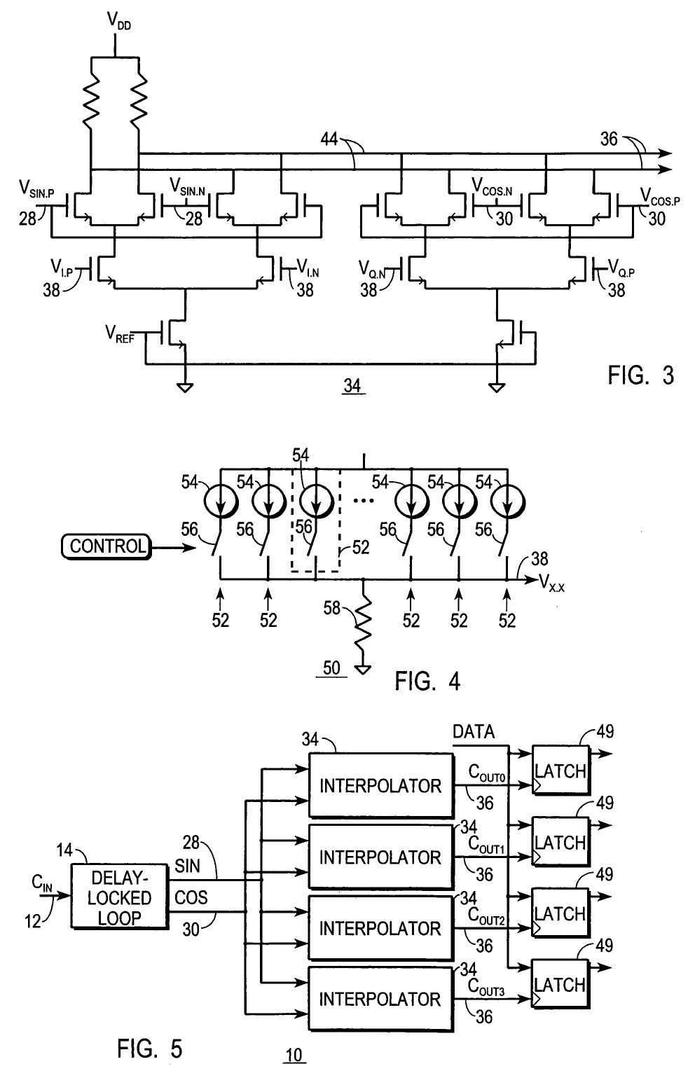

FIG. 3 shows a schematic diagram of one embodiment of an interpolator 34. In the FIG. 3 embodiment, V_{SIN.P} and V_{SIN.N} represent differential signals for ultimate-delayed clock signal 28, and V_{COS.P} and V_{COS.N} represent differential signals for penultimate-delayed clock signal 30. V_{I.P} and V_{I.N} provide differential signals for use in weighting ultimate-delayed clock signal 28, and V_{Q.P} and V_{Q.N} provide differential signals for use in weighting penultimate-delayed clock signal 30. Accordingly, output clock signal 36 can be expressed as:
C_{OUT}=(V_{I.P}−V_{I.N})·SIN(ωt)+(V_{Q.P}−V_{Q.N})·COS(ωt). EQ. 3
And, the resulting phase can be expressed as:
Φ=TAN⁻¹([V_{Q.P}−V_{Q.N}]/[V_{I.P}−V_{I.N}]). EQ. 4
The control voltages input in this FIG. 3 embodiment can be analog signals to achieve a continuously adjustable phase adjustment.

FIG. 4 shows a block diagram of a digital control element 50 which may be used in one embodiment of the present invention to adjust clock phase. FIG. 4 depicts only a single control element 50, but this control element 50 may be repeated for three additional iterations to obtain the four controls (i.e., V_{I.P}, V_{I.N}, V_{Q.P}, V_{Q.N}) used in the FIG. 3 embodiment of interpolator 34.

FIG. 4 depicts any number of switch paths 52, with each path 52 including a current generator 54 that sources substantially the same current as is sourced by the other current generators 54. Each switch path 52 also includes a switching element 56 in series with the current generator 54 of the switch path 52. One side of all switching paths 52 couple to a common voltage source, and the other side couples through a common resistive element 58 to a node adapted to receive a common potential, such as ground.

Assuming that digital control element 50 includes 2·M switch paths 52, where M is an integer, and the center operational point of the control is M·I·R, then:
V_{I.P} is obtained from closing M+L current branches 52, and V_{I.P}=(M+L)·I·R;
V_{I.N} is obtained from closing M-L current branches 52, and V_{I.N}=(M−L)·I·R;
V_{Q.P} is obtained from closing M+K current branches 52, and V_{Q.P}=(M+K)·I·R; and
V_{Q.N} is obtained from closing M−K current branches 52, and V_{Q.N}=(M−K)·I·R; and
   Φ=TAN⁻¹(K/L);

Where, L and K can be positive or negative integers,
|L|≦M, and |K|≦M.

A sufficient number of switch paths 52 can be included to achieve a desirably small phase resolution step size. The variables L and K can be selected such that L·L+K·K equals a constant to minimize amplitude changes. Moreover, it is the ratio of the generated control voltages to which the resulting clock phase responds. Consequently, symmetries easily obtainable using conventional semiconductor manufacturing processes makes the resulting control substantially independent of process variations.

FIG. 5 shows a block diagram of a second embodiment of clock phase adjuster 10 in accordance with the teaching of the present invention. In the FIG. 5 embodiment, delay-locked loop 14 generates ultimate- and penultimate-delayed clock signals 28 and 30 as discussed above. But interpolator 34 is duplicated any number of times, with each instance of interpolator 34 being driven by clock signals 28 and 30. Thus, by using independent control voltages for interpolators 34, as discussed above, multiple independent phases of a clock signal are generated. The multiple independent phases of clock signals 36 are then routed to receiving circuits 49 configured as latches having data inputs coupled to a common data source and clock inputs fed by the independent phases of clock signals 36. Thus, different phases of a data signal may be reliably captured in latches 49.

In summary, the present invention provides an improved clock phase adjuster. The amount of phase adjustment introduced by the clock phase adjuster is independent of IC processing vagaries. And, the amount of phase adjustment introduced by the clock phase adjuster may be continuously adjustable so as to have virtually no minimum step size.

Although the preferred embodiments of the invention have been illustrated and described in detail, it will be readily apparent to those skilled in the art that various modifications may be made therein without departing from the spirit of the invention or from the scope of the appended claims. For example, the analog control voltages “V” and “1−V” discussed above may be more accurately presented as “V” and “Sqrt(1−V·V)”. This embodiment would have the advantage of better maintaining clock amplitude, but it would be more complicated to implement. In addition, those of skill in the art will understand that the terms “ultimate” and “penultimate” are used herein only for consistency with the specifically described preferred embodiment to distinguish one from the other and imply no required absolute or relative relationship to one another. These and other modifications and understandings which are obvious to those skilled in the art are intended to be included within the scope of the present invention.

What is claimed is:

1. A phase adjuster comprising:
a delay-locked loop configured to receive a periodic input signal and to generate a first output signal phase-shifted N·Π radians from said input signal, and to generate a second output signal phase-shifted an amount other than N·Π radians from said input signal, where N is an integer number greater than or equal to one; and
an interpolator configured to receive said first and second output signals and a control signal and to output a phase-adjusted signal having a phase relative to said periodic input signal determined in response to said control signal.

2. A phase adjuster as claimed in claim 1 wherein said second output signal is phase-shifted less than N·Π radians.

3. A phase adjuster as claimed in claim 2 wherein said second output signal is phase-shifted ±Π/2 radians from said first output signal.

4. A phase adjuster as claimed in claim 2 wherein N=1 and said second output signal is phase-shifted Π/2 radians from said input signal.

5. A phase adjuster as claimed in claim 1 wherein said first and second output signals are in phase quadrature with one another.

6. A phase adjuster as claimed in claim 1 wherein said delay-locked loop is integrally formed on a solitary semiconductor substrate.

7. A phase adjuster as claimed in claim 1 wherein said delay-locked loop is further configured so that said first and second output signals are shifted by amounts of phase that are independent of the frequency of said input signal.

8. A phase adjuster as claimed in claim 1 wherein said delay-locked loop comprises:
a phase detector configured to receive said periodic input signal;
a loop filter coupled to said phase detector; and
a voltage-controlled delay line coupled to said phase detector and having at least two delay stages, where each delay stage has a control input coupled to said loop filter, and said at least two delay stages are configured to implement substantially identical delays at common control voltages provided by said loop filter.

9. A phase adjuster as claimed in claim 1 wherein said interpolator comprises:
a first multiplier adapted to receive said first output signal from said delay-locked loop;
a second multiplier adapted to receive said second output signal from said delay-locked loop; and
a combining circuit coupled to said first and second multipliers.

10. A phase adjuster as claimed in claim 9 wherein:
said first multiplier is an analog multiplier that is adapted to receive a first analog control signal;
said second multiplier is an analog multiplier that is adapted to receive a second analog control signal; and
said phase-adjusted signal is continuously adjustable in response to said first and second analog control signals.

11. A phase adjuster as claimed in claim 9 wherein:
said first multiplier is an analog multiplier that is adapted to receive a first analog control signal;
said second multiplier is an analog multiplier that is adapted to receive a second analog control signal; and
said interpolator additionally comprises:
a first digital control element having a plurality of first switch-paths, with each first switch-path having a switch in series with one of a plurality of substantially identical current sources, and having a common resistive element for all of said first switch-paths, said first digital control element being coupled to said first multiplier; and
a second digital control element having a plurality of second switch-paths, with each second switch-path having a switch in series with one of a plurality of substantially identical current sources, and having a common resistive element for all of said second switch-paths, said second digital control element being coupled to said second multiplier.

12. A method for adjusting the phase of an input clock signal comprising:
delaying said input clock signal in a first delay element of a delay-locked loop to generate a penultimate-delayed clock signal;
delaying said penultimate-delayed clock signal in a second delay element of said delay-locked loop to generate an ultimate-delayed clock signal;
locking phases of said ultimate-delayed clock signal and said input clock signal by operation of said delay-locked loop; and
interpolating between said penultimate-delayed clock signal and said ultimate-delayed clock signal by an amount determined by a control signal to generate a phase-adjusted clock signal having a phase relative to said clock signal determined in response to said control signal.

13. A method as claimed in claim 12 wherein said locking activity is configured so that said ultimate-delayed clock signal is phase-shifted N·Π radians from said input clock signal, and said penultimate-delayed clock signal is phase-shifted an amount other than N·Π radians from said input clock signal, where N is an integer number greater than or equal to one.

14. A method as claimed in claim 13 wherein said penultimate-delayed clock signal is phase-shifted ±Π/2 radians from said from said ultimate-delayed clock signal.

15. A method as claimed in claim 13 wherein N=1 and said penultimate-delayed clock signal is phase-shifted Π/2 radians from said input clock signal in said input-clock-signal-delaying activity.

16. A method as claimed in claim 12 wherein said input-clock-signal-delaying activity, said penultimate-delayed-clock-signal-delaying activity, and said locking activity collectively cause said penultimate-delayed clock signal and said ultimate-delayed clock signal to be locked in phase quadrature with one another.

17. A method as claimed in claim 12 additionally comprising conducting said input-clock-signal-delaying activity and said penultimate-delayed-clock-signal-delaying activity on a solitary semiconductor substrate upon which said delayed-locked loop is formed.

18. A method as claimed in claim 12 wherein said input-clock-signal-delaying activity, said penultimate-delayed-clock-signal-delaying activity, and said locking activity collectively cause said penultimate-delayed clock signal and said ultimate-delayed clock signal to be locked at a predetermined phase difference, and said method additionally comprises:
changing frequency of said input clock signal; and
maintaining said predetermined phase difference after said frequency-changing activity.

19. A method as claimed in claim 12 wherein said interpolating activity comprises:
multiplying said ultimate-delayed clock signal by a first control signal to produce a first scaled signal;
multiplying said penultimate-delayed clock signal by a second control signal to produce a second scaled signal; and
combining said first and second scaled signals.

20. An integrated circuit having a phase adjuster, said integrated circuit comprising:
a clock-generating circuit configured to generate a source clock signal;
a delay-locked loop configured to receive said source clock signal and to generate an ultimate-delayed clock signal phase-shifted N·Π radians from said source clock signal, and to generate a penultimate-delayed clock signal phase-shifted an amount other than N·Π radians from said source clock signal, where N is an integer number greater than or equal to one; and
an interpolator configured to receive said ultimate-delayed clock signal, said penultimate-delayed clock signal and a control signal, said interpolator being configured and to output a phase-adjusted clock signal having a phase relative to said source clock signal determined in response to said control signal; and
a receiving circuit coupled to said interpolator and configured to be responsive to said phase-adjusted clock signal.
